(19) United States
(12) Patent Application Publication
(10) Pub. No.: US 2025/0081517 A1
(43) Pub. Date: Mar. 6, 2025

(54) PROGRAMMABLE GATE DESIGN FOR MULTIPLE GATE TRANSISTOR

(71) Applicant: Alpha and Omega Semiconductor International LP, Toronto (CA)

(72) Inventors: Wenwen Li, Santa Clara, CA (US); Xiaobin Wang, San Jose, CA (US); Sik Lui, Sunnyvale, CA (US); Adithya Prakash, Santa Clara, CA (US); Lingpeng Guan, San Jose, CA (US); Madhur Bobde, Sunnyvale, CA (US)

(21) Appl. No.: 18/241,783

(22) Filed: Sep. 1, 2023

(51) Int. Cl. H01L 29/78; H01L 29/40; H01L 29/66

(52) U.S. Cl. CPC H10D 30/668; H10D 30/0297; H10D 64/117

(57) ABSTRACT

A multiple gate transistor and method of its manufacture are described. The transistor comprises a common substrate, a source, a drain, a body, a first gate electrode and a second gate electrode. The first gate electrode and the second gate electrode are colinearly aligned along a horizontal plane of the common substrate and are separated by a dielectric wall. The dielectric wall provides electrical isolation between the first gate electrode and the second gate electrode.

### FIELD OF THE DISCLOSURE

Aspects of the present disclosure relate to double gated transistors. More specifically, aspects of the present disclosure relate to double gated transistors having a programmable gate design.

### BACKGROUND OF THE DISCLOSURE

It has been found that the efficiency of a transistor varies based on the level of current being passed through the transistor at low voltages. This is because at low voltages there is a trade-off between reducing the resistance from drain to source (R_{ds}) and reducing gate driven capacitive losses. Increasing the gate voltage (V_{gs}) reduces R_{ds}, but problematically increases the gate drive capacitive losses. A MOSFET device with a large gate area allows for a higher V_{gs} while a device with smaller gate area provides for lower gate drive capacitance but cannot tolerate the higher V_{gs}. Thus, at low loads a Metal Oxide Semiconductor Field Effect Transistor (MOSFET) device with a smaller gate area may be more efficient as at low loads and high frequency gate drive capacitance losses in efficiency dominate over R_{ds} while at higher loads it may be more efficient to have a larger gate that can support a higher V_{gs} as losses from R_{ds} may dominate at normal or higher current loads.

A current solution to this issue is to have two switching devices of different sizes localized on the same substrate with one switching device being larger than the other. In high load conditions the larger switch or both switches may be used and in low load conditions the smaller switch may be used. FIG. 1 shows a schematic diagram of a prior art double gated n-channel MOSFET.

As shown the double gate n-channel MOSFET here has a common substrate and includes a common drain D and source S controlled by two gates G1 and G2. A diode D1 is formed from the PN junction between the drain D and the body region in the common substrate. This is the so-called antiparallel diode. In the prior art implementations, the width of the second switch W2 was a set factor of the width of the first switch W1; thus W2=nW1. An output terminal of a gate control may be coupled to the first gate G1. The gate control may be for example a gate driver and control the operation of the first gate by providing a pulse-width modulated signal to a terminal of the first gate. The second gate G2 may be connected to the output terminal of the gate control and the first gate G1 through a switch SW when the switch is closed. The second gate G2 is electrically isolated from the first gate when the switch is open.

Different applications for double gate devices may have different gate voltage and/or load requirements. In the prior art implementation of a double gate device the width of the gate is set early during the manufacturing stages meaning that the width of the first gate and second gate cannot be changed without redesigning the entire circuit. This means that for each application that has a different voltage or load requirement the entire double gate device must be redesigned to accommodate the application. On top of redesigning the layout of the device itself each of the manufacturing stages for the device must be changed to accommodate the new layout of the device. This means that it is very costly to accommodate new applications. Additionally prototyping device areas with different ratios of gate 1 to gate 2 is very expensive based on prior art techniques as the layout of the gate areas must be specifically designed based on the application.

It is within this context that aspects of the present disclosure arise.

### BRIEF DESCRIPTION OF THE DRAWINGS

The teachings of the present disclosure can be readily understood by considering the following detailed description in conjunction with the accompanying drawings, in which:

FIG. 1 is a schematic diagram of a prior art double gated n-channel MOSFET.

FIG. 2 is a top-view diagram showing a trench layout of a programmable gate design for a double gated transistor according to an aspect of the present disclosure.

FIG. 3 is a top-view diagram showing a gate oxide with a trench layout of the programmable gate design for a double gated transistor according to an aspect of the present disclosure.

FIG. 4 is a top-view diagram showing a gate metal layout having one hundred percent device area comprising gate one of the programmable gate design for a double gated transistor according to an aspect of the present disclosure.

FIG. 5 is a top-view diagram showing a gate metal layout having seventy-five percent device area comprising gate one and twenty-five percent of the device area comprising gate two of the programmable gate design for a double gated transistor according to an aspect of the present disclosure.

FIG. 6 is a top-view diagram showing a gate metal layout having sixty-two point five percent device area comprising gate one and thirty-seven point five percent of the device area comprising gate two of the programmable gate design for a double gated transistor according to an aspect of the present disclosure.

FIG. 7 is a top-view diagram showing a gate metal layout having fifty-five percent device area comprising gate one and fifty-five percent of the device area comprising gate two of the programmable gate design for a double gated transistor according to an aspect of the present disclosure.

FIGS. 8A-SM depict a method of manufacturing a double gated Shielded Gate Transistor (SGT) having the programmable gate design according to an aspect of the present disclosure.

FIG. 9 is a cutaway diagram of a double gated SGT at a step during manufacture after a gate electrode material has been deposited in the trenches according to aspects of the present disclosure.

FIG. 10 is a cutaway diagram of a double gated SGT after doping of the source area according to an aspect of the present disclosure.

FIG. 11A is a top-view diagram showing a planar gate layout of the programmable gate design for a double gated transistor according to an aspect of the present disclosure.

FIG. 11B is a side-view diagram showing the programmable gate design for a double gated planar gate transistor according to an aspect of the present disclosure.

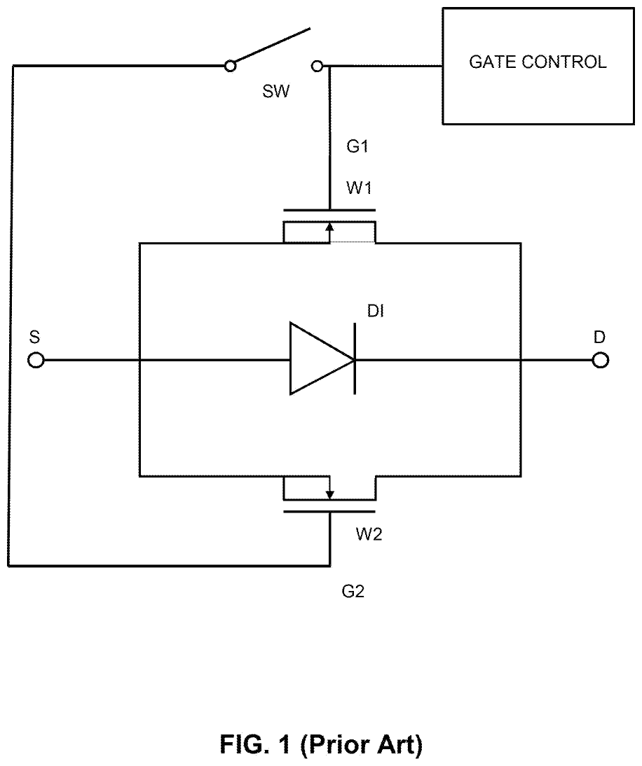

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the present disclosure. Accordingly, example embodiments of the present disclosure described below are set forth without any loss of generality to, and without imposing limitations upon, the claimed invention.

In the following Detailed Description, reference is made to the accompanying drawings, which form a part hereof, and in which are shown by way of illustration specific embodiments in which the invention may be practiced. In this regard, directional terminology, such as “top,” “bottom,” “front,” “back,” “leading,” “trailing,” etc., is used with reference to the orientation of the figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The disclosure herein refers to a semiconductor material, such as silicon, doped with ions of a first conductivity type or a second conductivity type. The ions of the first conductivity type may be opposite ions of the second conductivity type. For example, and without limitation, in some implementations, ions of the first conductivity type may be n-type, which contribute negative charge carriers, e.g., electrons, when doped into silicon. In such implementations, ions of the first conductivity type may include phosphorus, antimony, bismuth, lithium, and arsenic. In such implementations, ions of the second conductivity may be p-type, which create holes for charge carriers when doped into silicon and in this way are referred to as being the opposite of n-type. P-type type ions include boron, aluminum, gallium, and indium. While the above description referred to n-type as the first conductivity type and p-type as the second conductivity type the disclosure is not so limited, p-type may be the first conductivity type and n-type may be the second conductivity type. Furthermore, semiconductor materials other than silicon, such as germanium, silicon carbide and gallium arsenide, among others, may be used in MOSFET devices in accordance with aspects of the present disclosure.

In the following Detailed Description, reference is made to the accompanying drawings, which form a part hereof, and in which are shown by way of illustration of specific embodiments in which the invention may be practiced. For convenience, use of + or − after a designation of conductivity or net impurity carrier type (p or n) refers generally to a relative degree of concentration of a designated type of net impurity carriers within a semiconductor material. In general, terms, an n+ material has a higher n type net dopant (e.g., electron) concentration than an n material, and an n material has a higher carrier concentration than an n− material. Similarly, a p+ material has a higher p type net dopant (e.g., hole) concentration than a p material, and a p material has a higher concentration than a p- material. It is noted that what is relevant is the net concentration of the carriers, not necessarily dopant concentration. For example, a material may be heavily doped with n-type dopants but still have a relatively low net carrier concentration if the material is also sufficiently counter-doped with p-type dopants. As used herein, a concentration of dopants about 10¹⁶/cm³ may be regarded as “lightly doped” and a concentration of dopants greater than about 10¹⁸/cm³ may be regarded as “heavily doped”.

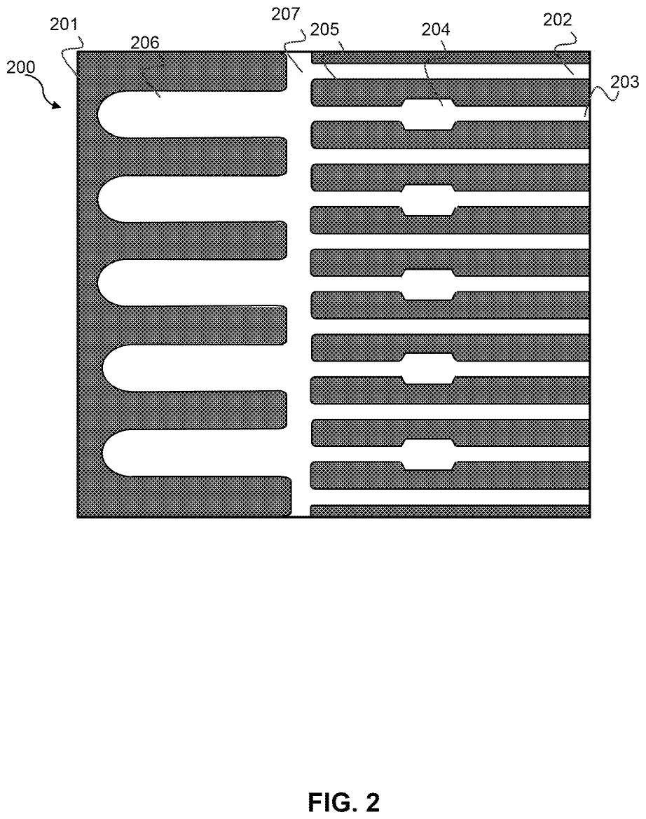

FIG. 2 is a top-view diagram showing a trench layout of a programmable gate design for a double gated shielded gate transistor according to an aspect of the present disclosure. As shown the device 200 includes a common substrate 201 having gate trenches 202 for the first gate, and trenches designated as split gate trenches 203. A portion 204 of the split gate trenches 203 may be widened to support the creation of vias through the gate electrode insulating layer. The trenches may also include a first gate trench gate contact area 206 enlarged for the creation of vias through the gate insulating layer as well as termination structure. The first gate trench may also include a lengthwise connection region 207 which connects first gate trenches 202 running width wise in the substrate and the first gate contact areas 206. At the stage of production shown the source regions have not yet been formed in the common substrate, but a source region 205 is visible between the gate trenches 202.

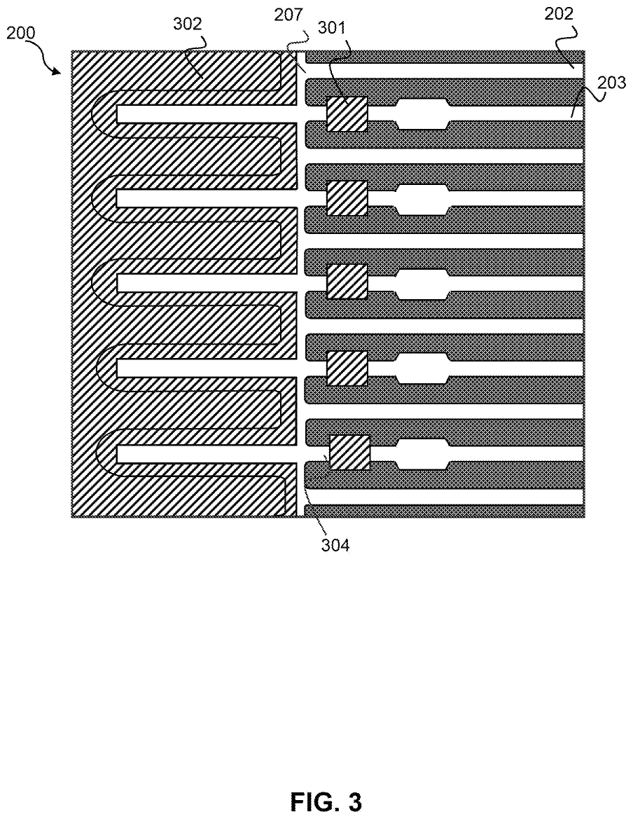

FIG. 3 is a top-view diagram showing a thick insulating layer with the trench layout of the programmable gate design for a double gated transistor according to an aspect of the present disclosure. As shown a dielectric wall 301 is formed in the split gate trenches 203. The first gate trenches 202 on the other hand are left intact ensuring that the width of gate one is always greater than gate two. Additionally shown is the first gate metal insulting layer 302. This layout allows the creation of gate electrodes in the split gate trenches that are colinearly aligned along a horizontal plane of the common substrate. The lengthwise connection regions 207 connect a portion of the gate electrode 304 in the split gate trenches making it part of the first gate electrode. The dielectric wall 301 separates the first gate electrode and the second gate electrode and the dielectric wall insulates the first gate electrode and the second gate electrode. One benefit of the design is that the dielectric wall can be formed at the same step as formation of inter poly oxide for a shielded gate MOSFET, which means no extra steps needed.

The benefit of the present design is that the ratio of device area taken up by gate one to gate two is easily customizable by changing the layout of the gate metal. Deposition of the gate metal is one of the final steps in device production and therefore it is easier to prototype devices with different ratios without completely redesigning regions of the device. The ratio can be adjusted by changing the patterning of the gate metal layer, which may be accomplished by changing a single mask. In general, the ratio depends on a number of lines of first gate electrode material that make electrical contact with the first gate metal. The ratio may also depend on a number of lines of second gate electrode material that make electrical contact with the second gate metal.

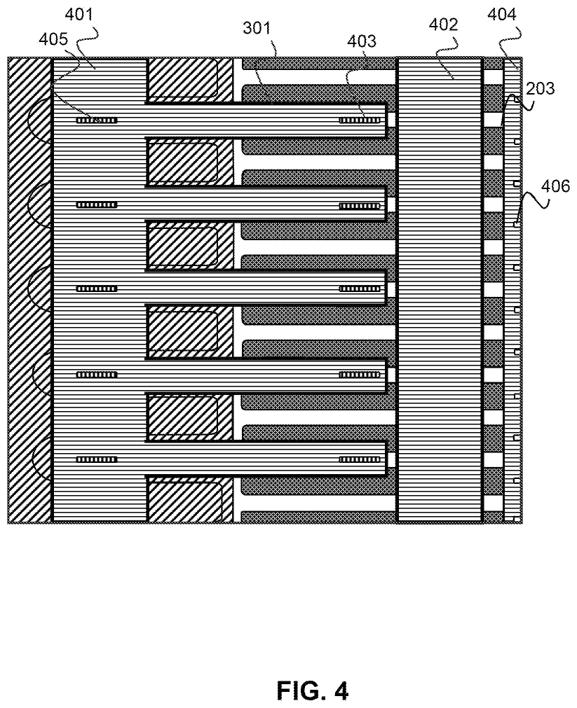

FIG. 4 is a top-view diagram showing a gate metal layout having one hundred percent device area comprising gate one of the programmable gate design for a double gated transistor according to an aspect of the present disclosure. In this implementation the first gate metal 401 includes fingers that extend over the dielectric wall 301 and over the via area of each of the split gate trenches. A source contact metal 404 makes contact with the source regions of the substrate composition and short the body region to the source region through plated source vias 406 through a source region insulating layer. A via 403 formed through the gate insulating layer conductively couples the gate metal with the gate electrode in the split gate trench. Vias 405 in the first gate contact area conductively couple the first gate metal to the gate trenches. Thus, in this implementation the first gate is connected to electrode material, e.g., polycrystalline silicon, on either side of the dielectric wall 301 in the split gate trench 203 meaning that the entire gate width of the device area is taken up by the first gate. The vias through an insulating layer may be formed through masking and etching of the insulating layer. Though the second gate metal 402 is disposed over the gate metal dielectric layer, no vias through the gate electrode insulating layer make contact with the second gate metal. As such none of the device area is comprised of the second gate.

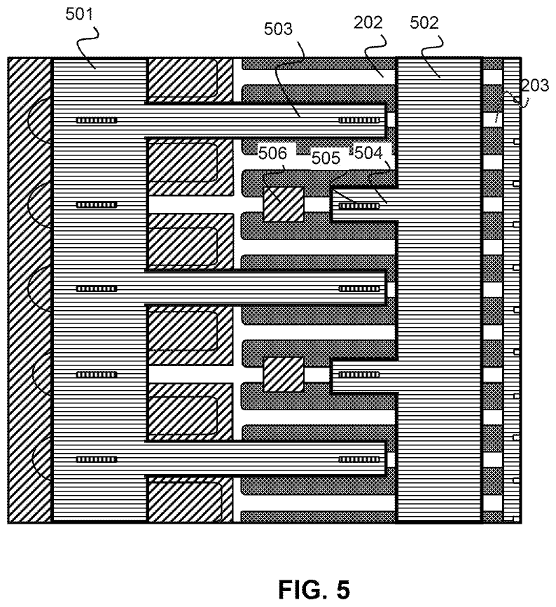

FIG. 5 is a top-view diagram showing a gate metal layout having seventy-five percent device area comprising gate one and twenty-five percent of the device area comprising gate two of the programmable gate design for a double gated transistor according to an aspect of the present disclosure. In this implementation the first gate metal includes three fingers 503 which cross over the dielectric wall 301 and make contact with the gate electrode in the split gate trench through vias 403. The second gate metal 502 includes two fingers 504 which extend over the gate via area of the split gate trenches 203. The second gate metal 502 is conductively coupled with the gate electrode in the split gate trench through vias 505. As shown dielectric walls 506 separate the second gate electrode which is conductively coupled to the second gate metal from the first gate electrode which is conductively coupled to the first gate metal. The first gate includes first gate trenches 202 which are filled with the first gate electrode. The substrate area alternates between the first gate trenches 202 and the split gate trenches 203. As such, seventy five percent of the gate area of the device is part of the first gate and twenty five percent of the gate area of the device is part of the second gate. As can be seen from FIG. 4 and FIG. 5 the ratio of device area taken up by gate one to gate two is controlled by the configuration of fingers in the first gate metal 501 and second gate metal 502. The layout of the substrate area including gate electrodes and vias remains the same between implementations.

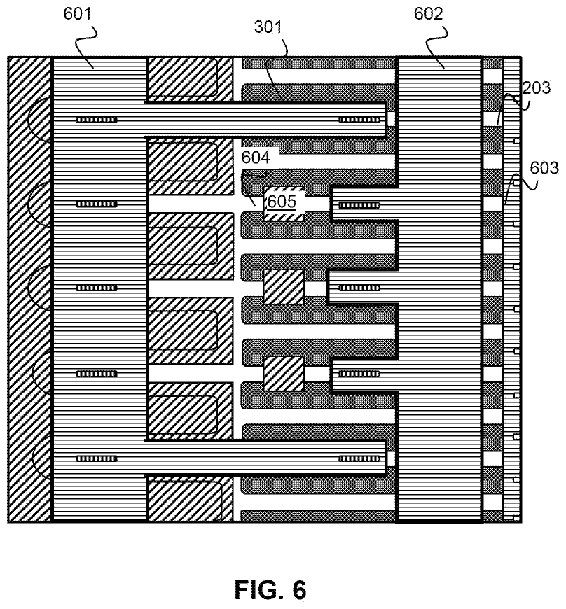

FIG. 6 is a top-view diagram showing a gate metal layout having sixty-two point five percent device area comprising gate one and thirty-seven point five percent of the device area comprising gate two of the programmable gate design for a double gated transistor according to an aspect of the present disclosure. In this implementation the first gate metal 601 includes two fingers that are each conductively coupled to a gate electrode in a respective split gate trench 203 the first metal is also in conductive contact with the first gate electrode in the first gate trenches and a portion of the split gate trench 203 on a side of the dielectric wall opposite the via is also conductively coupled to the first gate trench. The Second gate metal 602 includes three fingers which are each conductively coupled to a gate electrode in a respective split gate trench 203. Thus, sixty-two point five percent of the gate electrode area of the device is conductively coupled to the first gate metal and thirty-seven point five percent of the electrode area of the device is conductively coupled to the second gate.

In the split gate trenches that have gate electrodes conductively coupled to the second gate metal it can be seen that a portion of the split gate trench is filled with a gate electrode conductively coupled to the first gate (i.e. first gate electrode) 604 and a second portion of the split gate trench gate 603 with gate electrode conductively coupled to the second gate metal (i.e. second gate electrode). Here the first gate electrode 604 and second gate electrode 603 are thus colinearly aligned along a horizontal plane in the split gate trench formed in the common substrate separated by the dielectric wall 605.

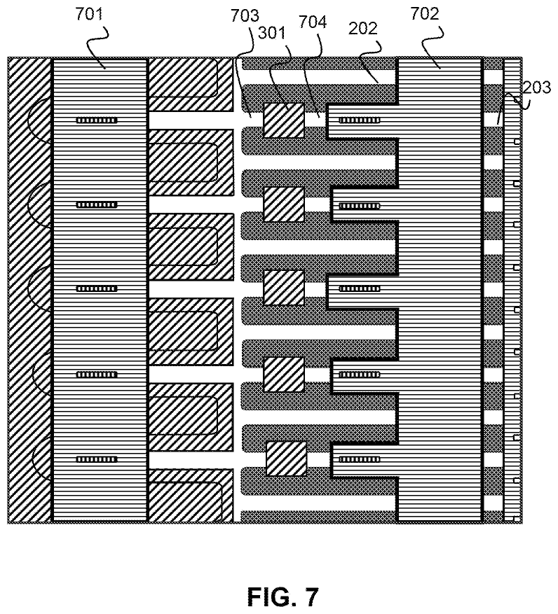

FIG. 7 is a top-view diagram showing a gate metal layout having fifty percent device area comprising gate one and fifty percent of the device area comprising gate two of the programmable gate design for a double gated transistor according to an aspect of the present disclosure. In the implementation shown the first gate metal 701 is conductively coupled to the gate electrode in the split gate trench 203 on a first side 703 of the dielectric wall 301 and the second gate metal 702 is conductively coupled to the gate electrode in the spit gate on a second side 704 of the dielectric wall 301. As seen the first gate metal is also conductively coupled to gate electrode material in the first gate trenches 202. As a result, the ratio of first gate electrode to second gate electrode is fifty percent.

While the implementations shown in FIG. 4 through FIG. 7 show six first gate trenches alternating with five split gate trenches, aspects of the present disclosure are not so limited. There may be any number of first gate trenches and any number of split gate trenches. Additionally, it is not required that the first gate trenches alternate with the split gate trenches. There may be any ratio of first gate trenches to split gates trenches for example there may be a first gate trench every two split gate trenches, three split gate trenches, four split gate trenches, etc. alternatively there may be a split gate trench every two first gate trenches, three gate trenches, four gate trenches, etc.

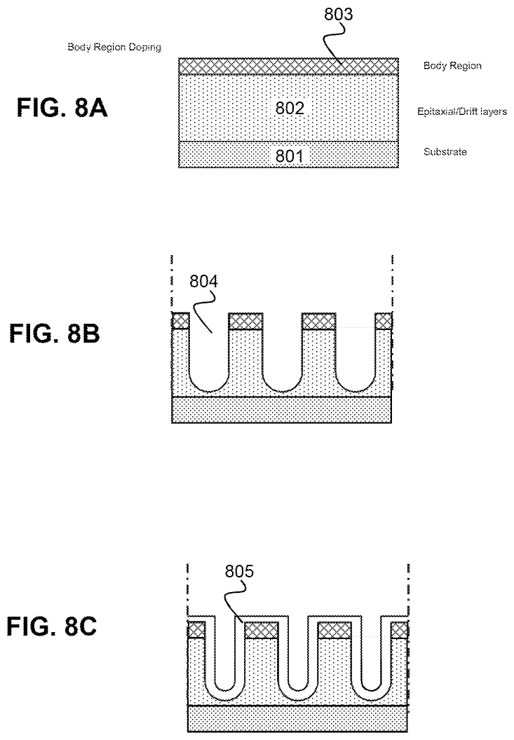

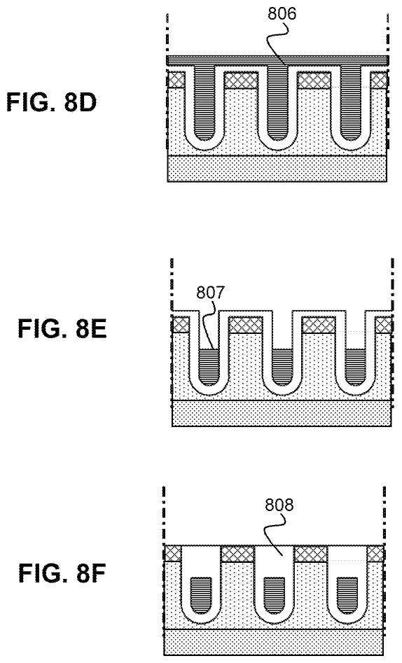

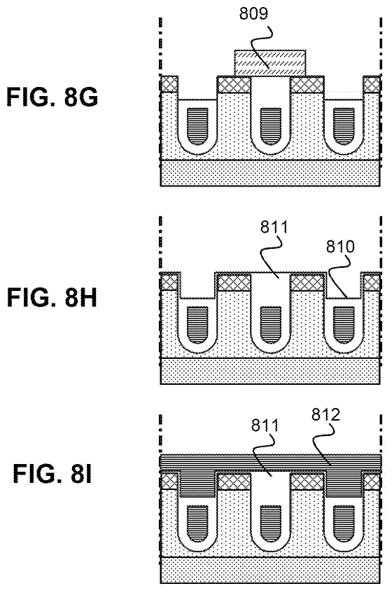

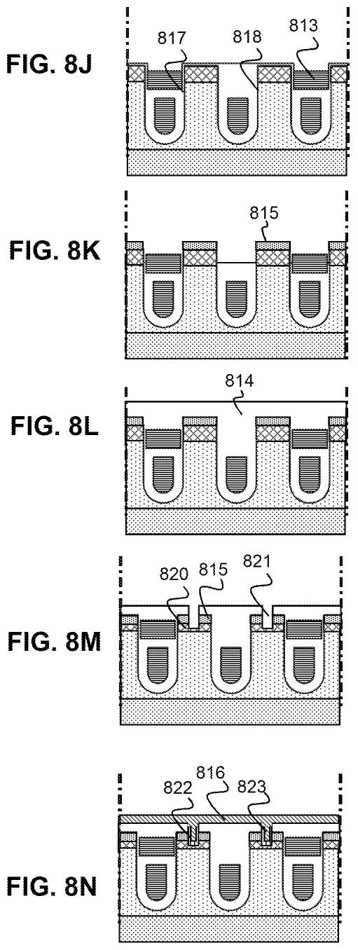

FIGS. 8A-8M depict a method of manufacturing a double gated Shielded Gate Transistor (SGT) having a programmable double gate design according to an aspect of the present disclosure. Initially as shown in FIG. 8A substrate 801 heavily doped with a first conductivity type may be provided. By way of example, the substrate may be N-type doped. An epitaxial layer/drift region 802 may be grown on the surface of the substrate 801. The epitaxial layer/drift region 802 may be lightly doped with ions of the first conductivity type. A body region 803 may then be formed in an upper portion of the epitaxial layer. The body region may be formed by implanting ions of a second conductivity type into selected portions of the epitaxial layer 802, where the second conductivity type is opposite the first conductivity type. Alternatively, the body region 803 may be formed by implantation just before the source implant after the formation of gates.

Trenches 804 may be formed in the substrate composition through the body region 803 and into the drift region 802. The trenches may be formed by any suitable trench formation method for example and without limitation reactive ion etching (IE), or anisotropic wet etching. The trenches 804 may be formed to a depth of about 1 micron or more. The trench pitch may be less than 1 micron and in one implementation the trench pitch may be for example and without limitation 0.6 microns. As shown in FIG. 8C the interior of the trenches and exposed surfaces of the substrate may be lined with a blanket insulating layer 805 which will eventually become a lower portion of the shield electrode insulating layer in the bottom of the trenches 804. The blanket insulating layer 805 and subsequently the shield electrode insulating layer may be made of for example and without limitation silicon dioxide. The blanket insulating layer 805 may be formed by any suitable method for example and without limitation Chemical vapor deposition (CVD) or thermal oxidation.

A shield electrode material 806 may be blanket deposited on the top surface of the blanket insulating layer 805. The shield electrode may be comprised of any conductive material, for example and without limitation polycrystalline silicon. The shield electrode material 806 may be deposited by any suitable method, for example and without limitation chemical vapor deposition. The shield electrode material may then be etched away from the surface of the device as shown in FIG. 8E. The etchant is chosen such that it selectively etches the surface of the substrate composition leaving the shield electrode 807 in a bottom portion of the trench.

A blanket inter-poly insulator layer 808, e.g., an oxide layer, may then be deposited on the surface of the substrate composition as shown in FIG. 8F. The top of the blanket interpoly insulator is then removed from a surface of the substrate composition exposing the top of the body region 803. The top of the blanket inter-poly insulator may be removed by any suitable method for example and without limitation chemical and mechanical polishing (CMP).

As shown in FIG. 8G an inter-poly insulator mask 809 is formed over a trench which will become the split gate trench. The inter-poly insulator layer 808 is then etched away from the surface of the substrate composition through openings in the mask 809 leaving the inter-poly insulator layer underneath the dielectric wall intact. The inter-poly insulator mask may be any suitable photoresist mask material. The inter-poly insulator is left in gate trenches 810 and forms the dielectric wall in 811 in the split gate trench. A blanket gate insulating layer is then applied over the substrate composition filling the gate trenches 810 over the inter-poly oxide as seen in FIG. 8H. The gate insulating layer may be for example and without limitation a silicon dioxide layer and may be formed by any suitable method for example and without limitation CVD or thermal oxidation.

Gate electrode material 812 is disposed on a surface of the gate insulating layer as shown in FIG. 8I. As can be seen the gate electrode material fills the gate trenches and does not fill an area of the trenches where the dielectric wall 811 is located. In the third dimension not shown the gate electrode material fills the split gate trench on either side of the dielectric wall. The gate electrode material 812 may be any suitable conductive material for example and without limitation polycrystalline silicon. The gate electrode material may be for example and without limitation deposited on the gate insulating layer via CVD.

Next as depicted in FIG. 8J, part of the gate electrode material 812 is etched away from the top surface of the substrate composition creating gate electrodes 813 in the first gate trenches 817 and on either side of the dielectric barrier of the split gate trenches 818. The dielectric wall electrically insulates the gate electrode material on one side of the split gate trench from the other side of the split gate trench. Any portions of the dielectric wall 811 that overly the body regions 803 may be stripped away and a blanket implant may be performed to create source regions 815, as shown in FIG. 8K. A source and gate insulation layer 814 may then be blanket deposited over the surface of the substrate composition, as shown in FIG. 8L. The source and gate insulation layer 814 may be comprised of, for example and without limitation, a dielectric material such as silicon dioxide and be formed with any suitable method such as CVD.

Source vias 821 are formed in through the source insulation later 814 and into the substrate composition to a depth deeper than source region 815 and at least exposing a surface of the body region 820. As shown here the source via terminated at a depth about halfway into the body region 820. The source vias 821 expose the body region for the creation of the source region and body short. The source vias may be formed by masking and any suitable dry etching method, such as reactive ion etching. The source regions 815 may be heavily doped with ions of the first conductivity type. After doping the source regions 815 into the body region the source mask may be removed by for example and without limitation chemical washing and/or CMP. A metal layer 816 is finally disposed on top of the substrate composition as depicted in FIG. 8N. The source metal makes contact with both the source regions and shorts the body region to the source regions through the plated source vias. The source metal may plate and fill the vias.

Alternatively, as shown here the sides 822 of the vias may be plated with a plating material such as aluminum, copper, tungsten, iron or any alloy thereof. The source metal layer may then fill the remaining space 823 in the source via. The gate electrodes are insulated from the source metal by the gate insulation layer. Selected portions of the metal layer are masked and etched away to form separate source metal and gate metal regions. The gate metal may be connected to gate contacts through vias, e.g., as shown in FIG. 4, FIG. 5, FIG. 6, and FIG. 7. A top metal insulating layer (not shown) may be deposited on top of the metal layer 816. Vias through the top metal insulating layer that are aligned with the vias in the gate electrode insulation may be formed by for example and without limitation masking and chemical etching, reactive ion etching or mechanical means. The vias allow a gate metal to contact the gate electrodes 813 in the trenches 817.

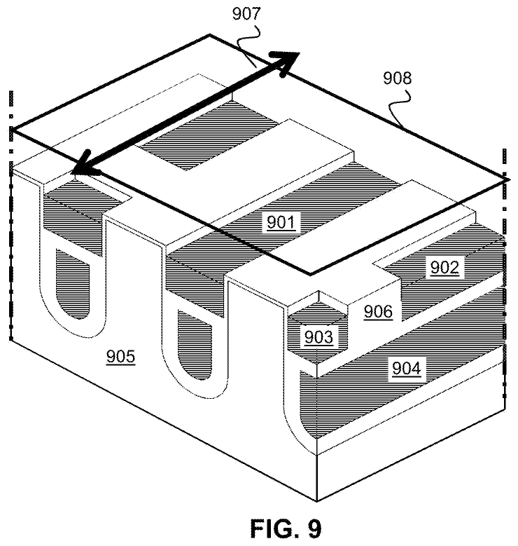

FIG. 9 is a cutaway diagram of a double gated SGT at a step during manufacture after a gate electrode material has been deposited in the trenches according to aspects of the present disclosure. This diagram corresponds to the manufacturing step seen FIG. 8J. In the device shown there are two split gate trenches which are separated by a first gate trench. As can be seen, the gate electrode is continuous in the first gate trench 901 and runs parallel to the split gate trenches with a portion of the substrate exposed between the trenches. The split gate trench has a first gate electrode 902 and a second gate electrode 903 located on either side of a dielectric wall 906. The first electrode and second electrode are colinearly aligned 907 along a horizontal plane 908 of the substrate composition. The Shield electrode 904 is continuous in both the split gate trenches and the first gate trenches.

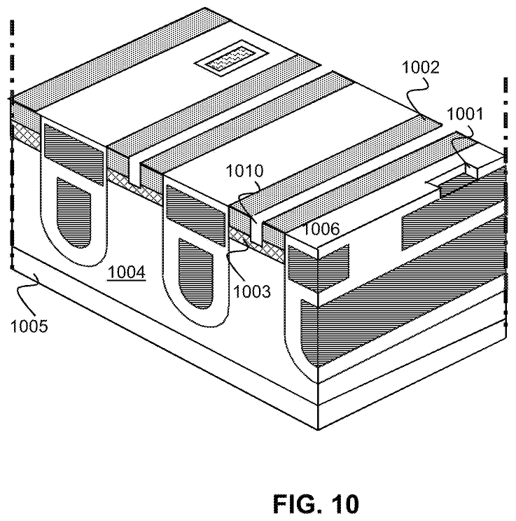

FIG. 10 is a cutaway diagram of a double gated SGT after doping of the source area according to an aspect of the present disclosure. Here to show the surface of the substrate composition, the gate metal, source metal and source insulating layers are not shown. In this view the vias 1001 through the gate electrode insulating layer 1006 can clearly be seen. In some implementations the gate electrode and trench may be widened in the via locations to better make contact between gate electrode and the gate metal through the via. The source regions 1002 run parallel with the first gate trenches and the split gate trenches in the body regions 1003. Source vias 1010 are formed in the substrate composition through the source regions 1002 and at least touching the body region 1003 allowing the source regions and body regions to be conductively coupled to the source metal and forming the source body short for the anti-parallel diode. Additionally, the drift region 1004 and substrate region 1005 can be seen.

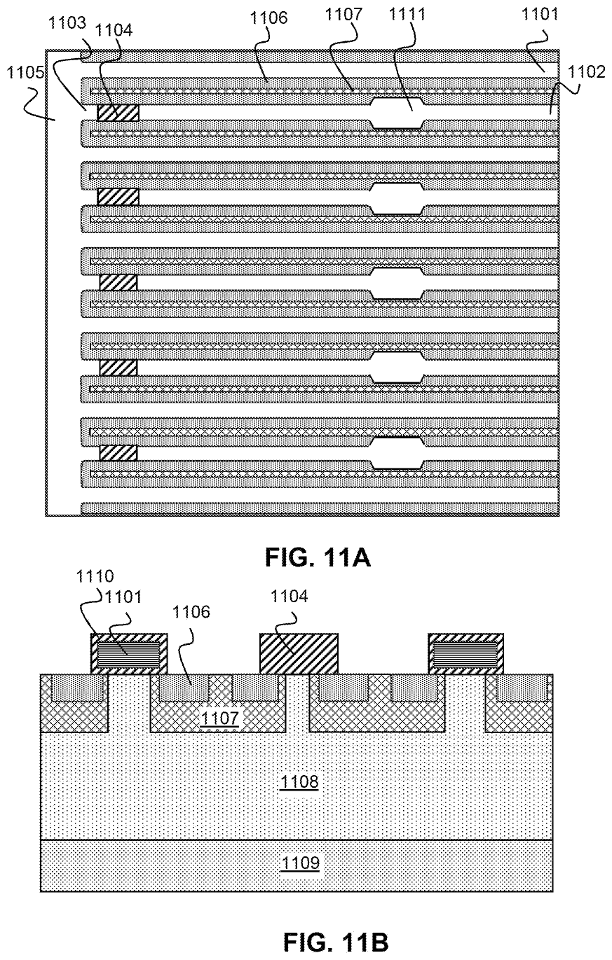

FIG. 11A is a top-view diagram showing a planar gate layout of the programmable gate design for a double gated transistor according to an aspect of the present disclosure. The top view of the layout for the planar gate device is very similar to the layout of the trench gate or SGT devices. In this implementation, the gate electrodes sit on the surface of the substrate composition with gate insulation layer separating the gate electrode from the surface of the substrate composition. The gates electrodes are disposed on the substrate composition in lines alternating between first gate electrodes 1101 and split gate electrodes 1102, 1103. A connection portion of the first gate electrode 1105 runs perpendicular to the first gate electrode lines 1101 connecting them. Additionally, the connection portion of the first gate electrode 1105 connects a shorter portion of the split gate electrodes 1102 on one side of the dielectric wall 1104 making it part of the first gate electrode. The longer portion of the split gate electrode 1103 on the other side dielectric wall 1104 may have an expended connection region 1111 to allow easier connection with the gate metal through vias in the insulation layer (not shown). In this implementation the dielectric wall 1104 is created from the gate insulating layer stacked on the surface of the substrate. The dielectric wall insulates the shorter portion 1103 of the split gate electrode from the longer portion 1102 of the split gate electrode.

In this view the source regions 1106 are visible. The source region 1106 are formed near the sides of the gate electrodes 1101, 1102, 1103 in the body region 1107 with a portion of the body region 1107 exposed allowing a short between the source region and body region to be created with the source metal (not shown).

FIG. 11B is a side-view cross-section diagram showing the programmable gate design for a double gated planar gate transistor according to an aspect of the present disclosure. As shown the first gate electrodes 1101 are disposed on the top surface of the substrate composition over the gate electrode insulating layer 1110. Additionally, the split gate electrodes (not shown) are disposed on the surface of the substrate composition and over the electrode insulating layer. The gate electrode insulating layer 1110 may surround the first gate electrode 1101 and split gate electrodes (not shown) and electrically isolate them from the substrate composition. The portion of the drift region 1108 may be located underneath the gate electrode insulating layer 1110 in the substrate composition. The body region 1107 is formed in an upper portion of the drift region 1108 and the source regions 1106 are formed in an upper portion of the body region 1107. The drift region 1108 may be formed on a substrate layer 1109.

As shown, the dielectric wall 1104 is formed on the top surface of the substrate composition. The dielectric wall may be formed with the gate insulation layer and additional insulation material may be deposited on the gate insulation layer to create the dielectric wall.

While implementations shown throughout this disclosure depict a substrate with fixed ratio of first gate trenches to split gate trenches (or lines in the case of planar gate layouts) aspects of the present disclosure are not so limited and there may be any number of first gate lines to split gate lines for example and without limitation there may be one first gate trench every two split gate trenches, three split gate trenches, four split gate trenches etc. It should also be understood that a larger number of split gate trenches to first gate trenches may allow for greater customizability but with some loss in gate width as space in the split gate trench is lost due to the dielectric wall. The first gate trenches limit the overall ratio of first gate trenches to second gate trenches thus in the implementations discussed the first trenches may make up more substrate area. As such the first gate may be able to accommodate higher loads than the second gate while the second gate may have less capacitive losses and be more efficient at low load.

The layout shown in FIG. 11A and FIG. 3 beneficially allows the selection of the ratio of a first gate to a second gate by changing a metal layout. This is particularly useful because it allows the use of a single substrate layout for different applications which may have different load requirements. In prior devices, a new gate layout would be needed to accommodate devices having different load requirements. A redesign of the gates would be needed to achieve the requirements, meaning that for each application having different requirements an entirely new device must be designed and built. Aspects of the present disclosure provide a substrate area layout that is generalized and may be easily customized for different applications with different load requirements without a complete redesign. Here, the last few steps in production, gate metal masking and gate metal deposition, may be changed to meet the requirements of a particular application. This saves time redesigning the gate layout and money working up new production equipment and samples. Although various implementations relating to MOSFET devices having multiple gates are discussed herein, those skilled in the art will recognize that such implementations may be adapted to other types of transistors, such as insulated gate bipolar transistors (IGBTs) and junction field effect transistors (JFETs).

While the above is a complete description of the preferred embodiment of the present invention, it is possible to use various alternatives, modifications, and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A,” or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A multiple gate transistor comprising: a common substrate, a source, a drain, a body, a first gate electrode and a second gate electrode, wherein said first gate electrode and said second gate electrode are colinearly aligned along a horizontal plane of the common substrate and are separated by a dielectric wall and wherein the dielectric wall provides electrical isolation between the first gate electrode and the second gate electrode.

2. The transistor of claim 1 further comprising a gate control, wherein the first gate electrode being connected to an output terminal of said gate control, the second gate electrode being connected to said output terminal through a switch and the first gate electrode and second gate electrode are electrically isolated from each other when the switch is open.

3. The transistor of claim 1 wherein the first gate electrode and second gate electrode are colinearly arranged in two or more lines along the horizontal plane of the common substrate.

4. The transistor of claim 3 further comprising a first gate metal and second gate metal, wherein a ratio of the first gate electrode to the second gate electrode in an area of the common substrate depends on a number of lines of first gate electrode material that make electrical contact with the first gate metal.

5. The transistor of claim 4 wherein the ratio of the first gate to the second gate in the area of the common substrate further depends on a number of lines of second gate electrode material that make electrical contact with the second gate metal.

6. The transistor of claim 1 wherein the first gate electrode includes a first gate polycrystalline silicon layer disposed in a gate trench and the second gate electrode includes a second gate polycrystalline silicon disposed in the gate trench wherein the dielectric wall separates the first gate poly from the second gate poly.

7. The transistor of claim 6 further comprising a shield electrode in the gate trench, wherein the shield electrode runs underneath both first gate electrode and the second gate electrode in the gate trench wherein the shield electrode is electrically isolated from the first gate electrode and the second gate electrode.

8. The transistor of claim 1 wherein the first gate electrode includes a first gate polycrystalline silicon layer disposed over an insulating layer on the horizontal plane of the common substrate and wherein the second gate electrode includes a second gate polycrystalline silicon layer disposed over the insulating layer.

9. A method of making a multiple gate transistor comprising:
a) forming a gate trench in a substrate;
b) depositing a gate electrode insulating layer on a surface in the gate trench;
c) selectively etching the gate insulating layer to create a dielectric wall in a portion of the gate trench;
d) depositing a conductive layer over the etched gate electrode insulating layer; and
e) etching portions of the conductive layer to form a first gate electrode and a second gate electrode wherein the dielectric wall separates the first gate electrode from the second gate electrode.

10. The method of claim 9 further comprising depositing a shield electrode insulating layer on a bottom of the trench and forming a shield electrode on the shield electrode insulating layer wherein the gate insulating layer is formed over the shield electrode and the shield electrode runs underneath both the first gate electrode and the second gate electrode.

11. The method of claim 9 wherein a. includes forming at least one additional gate trench in the substrate, wherein b) includes depositing the gate electrode insulating layer on a surface of the at least one additional gate trench, wherein c) includes selectively etching the at least one additional gate trench to create the dielectric wall in a portion of the at least one additional gate trench.

12. The method of making of claim 11 further comprising depositing a top insulating layer over the first gate electrode and the second gate electrode, wherein the top insulating layer includes vias exposing a portion of the first gate electrode and forming a first gate metal over the top insulating layer.

13. The method of claim 12 wherein a ratio of the first gate electrode to the second gate electrode in an area of the common substrate depends on a number of lines of first gate electrode material that make electrical contact with the first gate metal.

14. The method of claim 13 further comprising forming a second gate metal over the top insulating layer and wherein a ratio of the first gate electrode to the second gate electrode in an area of the common substrate further depends on a number of lines of second gate electrode material that make electrical contact with the second gate metal.

15. A multiple gate transistor comprising:
a lightly doped epitaxial layer of a first conductivity overlaying a heavily doped common substrate of the first conductivity;
a first trench gate disposed in a first trench section extending into the epitaxial layer and a second trench gate disposed in a second trench section extending into the epitaxial layer, wherein the first trench gate is electrically isolated from the second trench gate;
a source layer of the first conductivity disposed on a top surface of the epitaxial layer surrounding the first trench gate and the second trench gate, regions of the source layer separated by the first trench section and the second trench section are electrically connected; and
a common drain disposed on a bottom of the common substrate.

16. The transistor of claim 15 further comprising a body layer of second conductivity disposed in the epitaxial layer below the source layer.

17. The transistor of claim 15 wherein the first trench section and the second trench section are colinearly aligned along a horizontal plane of the common substrate and are separated by a dielectric wall and wherein the dielectric wall provides electrical isolation between the first gate and the second gate.

18. The transistor of claim 17 wherein the first trench gate and second trench gate are colinearly arranged in two or more lines along the horizontal plane of the common substrate.

19. The transistor of claim 18 wherein the first trench gate includes a first gate polycrystalline silicon layer disposed in the first trench section and the second trench gate includes a second gate polycrystalline silicon disposed in the second trench section wherein the dielectric wall separates the first gate polycrystalline silicon layer from the second gate polycrystalline silicon layer.

20. The transistor of claim 19 further comprising a shield electrode runs underneath both first trench gate and the second trench gate in a gate trench wherein the shield electrode is electrically isolated from the first trench gate and the second trench gate.
